(19) United States
(12) Patent Application Publication
(10) Pub. No.: US 2024/0321921 A1
(43) Pub. Date: Sep. 26, 2024

(54) IMAGE SENSOR INCLUDING DEVICE ISOLATION STRUCTURE

(71) Applicant: Samsung Electronics Co., Ltd., Suwon-si (KR)

(72) Inventors: Seounghyun KIM, Suwon-si (KR); Changhyo KOO, Suwon-si (KR); Sangchun PARK, Suwon-si (KR); Kwanghee LEE, Suwon-si (KR); Wook LEE, Suwon-si (KR); Haeyeon CHUNG, Suwon-si (KR)

(73) Assignee: Samsung Electronics Co., Ltd., Suwon-si (KR)

(21) Appl. No.: 18/610,413

(22) Filed: Mar. 20, 2024

(30) Foreign Application Priority Data
Mar. 24, 2023 (KR) 10-2023-0038963
Apr. 27, 2023 (KR) 10-2023-0055659

(51) Int. Cl. H01L 27/146

(52) U.S. Cl. CPC H01L 27/1463; H01L 27/14627; H01L 27/14634; H01L 27/14645

(57) ABSTRACT

Provided is an image sensor including a device isolation structure. The image sensor includes a semiconductor substrate including a pixel array including a plurality of pixels, a first photoelectric conversion device and a second photoelectric conversion device inside the semiconductor substrate and included in each of the plurality of pixels, microlenses on the first photoelectric conversion device and the second photoelectric conversion device and a device isolation structure between the plurality of pixels and between the first photoelectric conversion device and the second photoelectric conversion device, the device isolation structure opening a part between the first photoelectric conversion device and the second photoelectric conversion device, including an open region at each edge of the plurality of pixels, and may be continuous in the pixel array.

### CROSS-REFERENCE TO RELATED APPLICATION

This application is based on and claims priority under 35 U.S.C. § 119 to Korean Patent Application Nos. 10-2023-0038963, filed on Mar. 24, 2023, and 10-2023-0055659, filed on Apr. 27, 2023, in the Korean Intellectual Property Office, the disclosures of which are incorporated by reference herein in their entireties.

### BACKGROUND

The inventive concepts relates to image sensors, and more particularly, to image sensors including a device isolation structure.

An image sensor for capturing an image and converting the image into an electrical signal is also used in a general consumer electronic device such as a digital camera, a mobile phone camera, and a portable camcorder, as well as a camera mounted on a vehicle, a security device, and a robot.

Recently, auto focusing (AF), which automatically detects the focus of image sensors, has been widely used. In particular, various studies on phase difference auto focusing (PAF) technology are being conducted according to the characteristics of fast focus detection speed. In the PAF, a focal length is adjusted by automatically driving a focusing lens so that light transmitted through a photographing lens is divided and detected in different focus detection pixels and the detection signal has the same intensity in the same phase.

### SUMMARY

The inventive concepts provide image sensors having a device isolation structure including an open region.

In addition, the tasks to be solved by the technical ideas of this inventive concepts are not limited to the tasks mentioned above, and other tasks may be clearly understood by one of ordinary skill in the art from the following description.

According to some aspects of the inventive concepts, there is provided an image sensor including a semiconductor substrate including a pixel array including a plurality of pixels, a first photoelectric conversion device and a second photoelectric conversion device inside the semiconductor substrate and included in each of the plurality of pixels, microlenses on the first photoelectric conversion device and the second photoelectric conversion device and a device isolation structure between the plurality of pixels and between the first photoelectric conversion device and the second photoelectric conversion device, the device isolation structure opening a part between the first photoelectric conversion device and the second photoelectric conversion device, including an open region at each edge of the plurality of pixels, and may be continuous in the pixel array.

According to some aspects of the inventive concepts, there is provided an image sensor including a first photoelectric conversion device and a second photoelectric conversion device inside a semiconductor substrate and included in each of a plurality of pixels, microlenses on the first photoelectric conversion device and the second photoelectric conversion device a first device isolation structure between the plurality of pixels, and a second device isolation structure between the first photoelectric conversion device and the second photoelectric conversion device, the second device isolation structure opening a part between the first photoelectric conversion device and the second photoelectric conversion device, including an internal open region at each edge of the plurality of pixels, and the first device isolation structure and the second device isolation structure may contact each other.

According to some aspects of the inventive concepts, there is provided an image sensor including a first chip including a semiconductor substrate including a device isolation structure isolating a plurality of pixels, and a second chip under the first chip, and including a negative voltage generator configured to apply a negative voltage to the device isolation structure, the first chip including a first photoelectric conversion device and a second photoelectric conversion device formed inside the semiconductor substrate and included in each of the plurality of pixels, and microlenses on the first photoelectric conversion device and the second photoelectric conversion device and the device isolation structure is between the first photoelectric conversion device and the second photoelectric conversion device, and the device isolation structure opening a part between the first photoelectric conversion device and the second photoelectric conversion device, including an internal open region at each edge of the plurality of pixels, and may be continuous in the first chip.

### BRIEF DESCRIPTION OF THE DRAWINGS

Example embodiments of the inventive concepts will be more clearly understood from the following detailed description taken in conjunction with the accompanying drawings in which:

FIG. 1 is a block diagram illustrating an image sensor according to some example embodiments;

FIG. 2 is a vertical cross-sectional view illustrating a structure of a pixel array according to some example embodiments;

FIG. 3 is a circuit diagram of a pixel included in the pixel array of FIG. 1;

FIG. 4A is a diagram of a pixel included in an image sensor according to some example embodiments, and FIG. 4B is a cross-sectional view taken along line A1-A2 of FIG. 4A;

FIGS. 5 to 11 are diagrams of a pixel included in an image sensor according to some example embodiments;

FIGS. 12A and 12B are diagrams of a pixel array included in an image sensor according to some example embodiments;

FIGS. 13A and 13B are diagrams of a pixel array included in an image sensor according to some example embodiments;

FIGS. 14A and 14B are diagrams of a pixel array included in an image sensor according to some example embodiments;

FIG. 15 is a diagram illustrating a pixel array of an image sensor according to some example embodiments; and

FIGS. 16 and 17 are diagrams illustrating image sensors according to some example embodiments.

### DETAILED DESCRIPTION

Hereinafter, example embodiments of the inventive concepts will be described in detail with reference to the accompanying drawings.

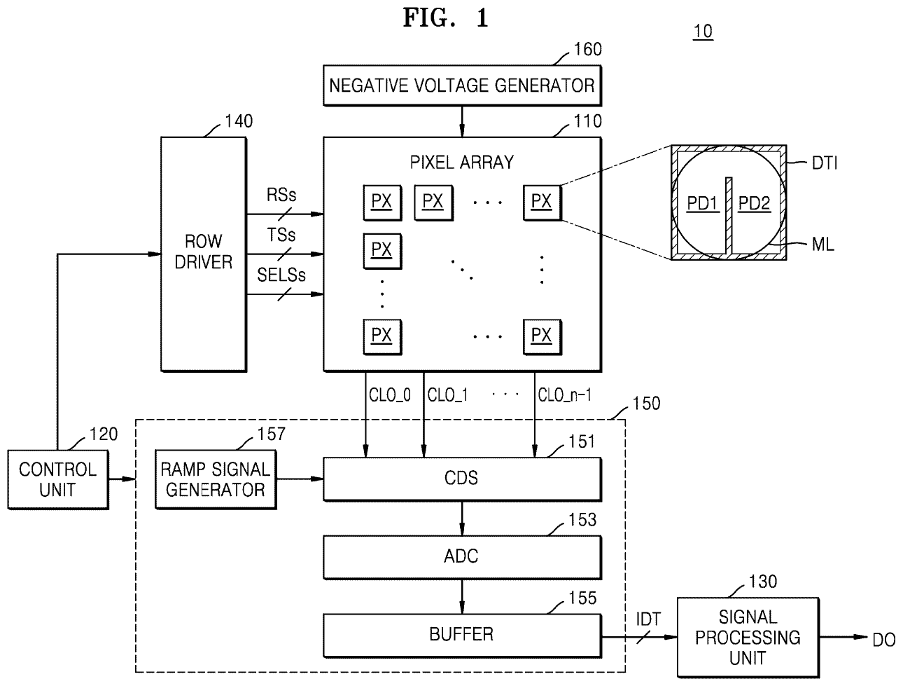

FIG. 1 is a block diagram illustrating an image sensor 10 according to some example embodiments.

Referring to FIG. 1, the image sensor 10 may include a pixel array 110, a control unit 120, a signal processing unit 130, a row driver 140, and a read-out circuit 150. The read-out circuit 150 may include: a correlated-double sampler (CDS) 151; an analog-digital converter (ADC) 153; and a buffer 155.

The pixel array 110 may include a plurality of pixels PXs that convert an optical signal into an electrical signal and are arranged two-dimensionally. Each of the plurality of pixels PXs may generate pixel signals according to the sensed intensity of light. Each of the pixels PXs may be implemented as, for example, a photoelectric conversion device such as a charge coupled device (CCD) or a Complementary Metal Oxide Semiconductor (CMOS), and may be implemented as various types of photoelectric conversion devices. The pixel array 110 may include a color filter to sense various colors, and each of the plurality of pixels PXs may sense a corresponding color. The pixel array 110 may output pixel signals to the CDS 151 through corresponding first to n-th column output lines CLO_0 to CLO_n−1.

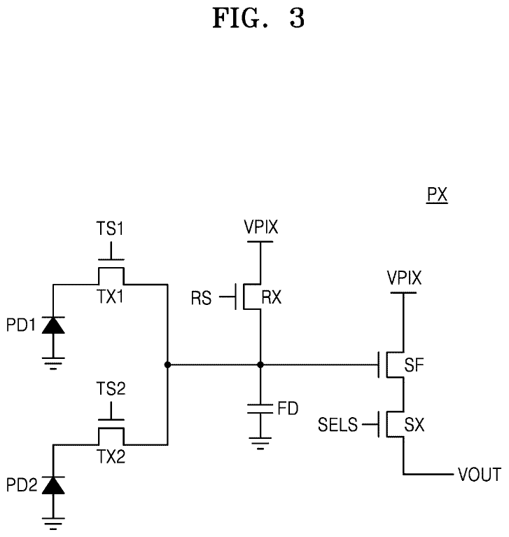

The pixel array 110 may include the plurality of pixels PXs. Each of the plurality of pixels PXs may be defined by a device isolation structure DTI. The pixel PX may include a plurality of photoelectric conversion devices, for example, a first photoelectric conversion device PD1 and a second photoelectric conversion device PD2, and may absorb light to generate photocharges. For example, the photoelectric conversion device may be a photodiode. In some example embodiments, photocharges generated in each of the first photoelectric conversion device PD1 and the second photoelectric conversion device PD2 included in the same pixel PX may accumulate in one floating diffusion region. An example circuit corresponding to the pixel PX is described below with reference to FIG. 3.

Each of the plurality of pixels PXs may include one microlens ML. All of the plurality of pixels PXs included in the pixel array 110 may be auto focusing (AF) pixels capable of performing an AF function and may be used to focus on an object.

Depending on the shape and refractive index of the microlens ML, the phase of the pixel signal generated in the pixel PX where one microlens ML is arranged may vary. In some example embodiments, the first photoelectric conversion device PD1 and the second photoelectric conversion device PD2 included in the pixel PX may be arranged in parallel to each other in a first direction (e.g., in a row direction). The AF function in the first direction may be performed based on the phase difference between a first pixel signal according to the photocharges generated by the first photoelectric conversion device PD1 and a second pixel signal according to the photocharges generated by the second photoelectric conversion device PD2. Otherwise, the first photoelectric conversion device PD1 and the second photoelectric conversion device PD2 included in the pixel PX may be arranged in parallel to each other in a second direction (e.g., in a column direction). The AF function in the second direction may be performed based on the phase difference between a first pixel signal according to the photocharges generated by the first photoelectric conversion device PD1 and a second pixel signal according to the photocharges generated by the second photoelectric conversion device PD2. As a result of performing the AF function, the focal position of a lens of an electronic device provided with the image sensor 10 may be calculated. For example, the position of the lens that makes the phase difference zero may be the focal position.

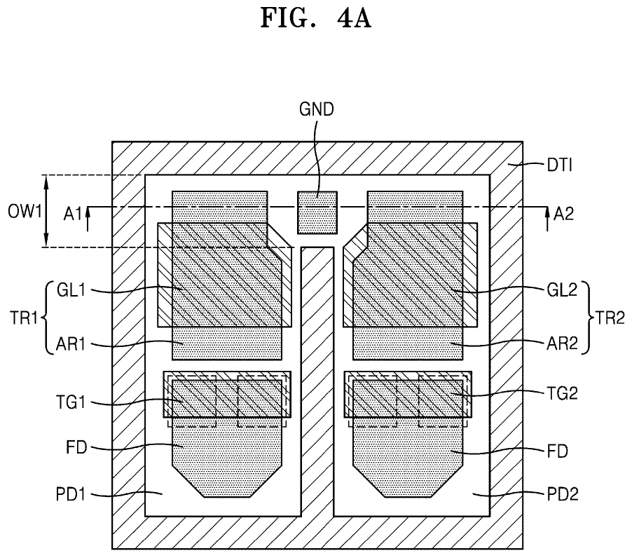

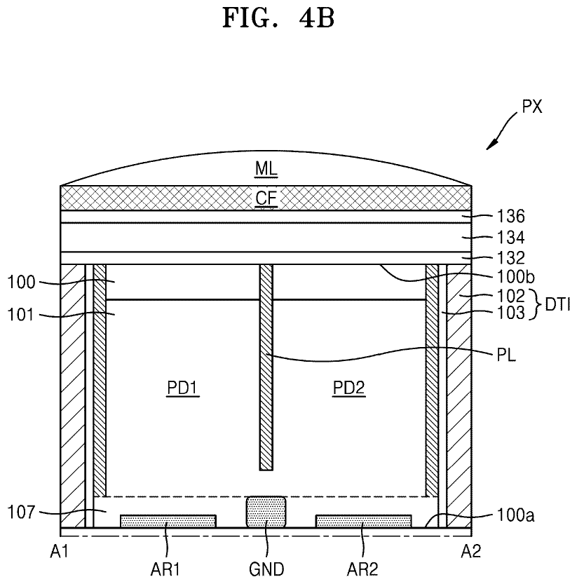

A device isolation structure DTI may be arranged between a region where the first photoelectric conversion device PD1 is formed and a region where the second photoelectric conversion device PD2 is formed, and the first photoelectric conversion device PD1 and the second photoelectric conversion device PD2 may be separated by the device isolation structure DTI. The device isolation structure DTI may include an open region arranged at the edge of the pixel PX, and a portion between the first photoelectric conversion device PD1 and the second photoelectric conversion device PD2 may be opened (exposed) by the open region. Therefore, as the open region is formed in the edge of the pixel PX, the movement of the photocharges generated in each of the first photoelectric conversion device PD1 and the second photoelectric conversion device PD2 through the open region may be limited and the AF contrast characteristic may be improved. In addition, in forming a charge overflow barrier (e.g., PL of FIG. 4B) of photocharges formed in the open region, it may be possible (for example, easily) to adjust the width of the open region and the width of the charge overflow barrier as the open region is placed at the edge of the pixel PX.

The control unit 120 may control the row driver 140 so that the pixel array 110 absorbs light to accumulate photocharges, temporarily stores the accumulated photocharges, and outputs the pixel signal according to the stored photocharges to the outside of the pixel array 110. In addition, the control unit 120 may control the read-out circuit 150 to measure the level of the pixel signal provided by the pixel array 110.

The row driver 140 may generate signals RSs, TSs, and SELSs for controlling the pixel array 110 and may provide the generated signals to the pixel array 110. In some example embodiments, the row driver 140 may determine the activation and deactivation timing of the reset control signals RSs, transmission control signals TSs, and selection signals SELSs provided to the pixels PXs depending on whether the AF function is performed.

The CDS 151 may sample and hold the pixel signal provided from the pixel array 110. The CDS 151 may double sample the level of specific noise (reset level) and the level according to the image signal (image level) and output a level corresponding to the difference. In addition, the CDS 151 may receive a ramp signal generated by a ramp signal generator 157 and compare the ramp signal with the pixel signal to output a comparison result.

The ADC 153 may convert an analog signal corresponding to a level received from the CDS 151 into a digital signal. The buffer 155 may latch the digital signal, and the latched digital signal may be sequentially output to the signal processing unit 130 or the outside of the image sensor 10 as image data.

The signal processing unit 130 may perform signal processing on image data output from the readout circuit 150. For example, the signal processing unit 130 may perform noise reduction processing, gain adjustment, waveform shaping processing, interpolation processing, white balance processing, gamma processing, edge emphasis processing, etc. In addition, the signal processing unit 130 may output the information which is signal-processed during the AF operation to a processor of the electronic device including the image sensor to allow the processor to perform a phase difference operation for the AF operation, or may perform a phase difference operation for the AF operation within the signal processing unit 130. In some example embodiments, the signal processing unit 130 may be provided in a processor outside the image sensor 10.

A negative voltage generator 160 may generate a negative voltage and provide an output voltage of the negative voltage to the pixel array 110. The output voltage of the negative voltage may be applied to the device isolation structure DTI of the pixel array 110. As a negative voltage is applied to the device isolation structure DTI, dark current characteristics may be improved and the reliability of the image sensor 10 may be improved. The device isolation structures DTIs formed in the pixel array 110 of the image sensor 10 according to some example embodiments may be physically connected to each other without separation. Accordingly, it may be possible (for example, easily) to apply a voltage to the device isolation structure DTI.

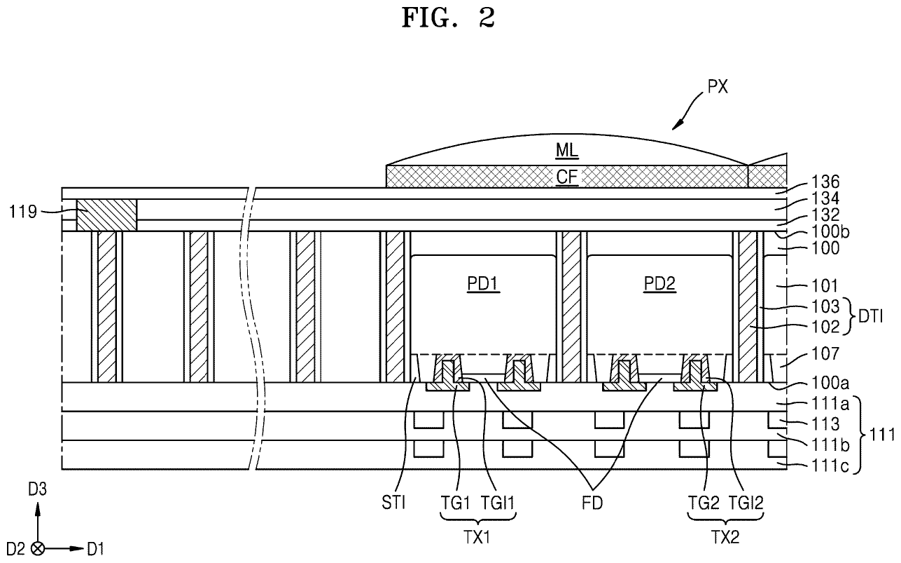

FIG. 2 is a vertical cross-sectional view illustrating a structure of a pixel array 110 according to some example embodiments.

Referring to FIG. 2, the image sensor 10 may include a semiconductor substrate 100. The semiconductor substrate 100 may have a first surface 100a and a second surface 100b opposite to each other. For example, the first surface 100a may be a front surface of the semiconductor substrate 100 and the second surface 100b may be a rear surface of the semiconductor substrate 100. Circuits may be arranged on the first surface 100a, and light may be incident on the second surface 100b.

A plurality of pixels PXs may be arranged in a matrix shape in rows and columns in a first direction D1 parallel to the main surface of the semiconductor substrate 100 and a second direction D2 perpendicular to the first direction D1 and in parallel to the main surface of the semiconductor substrate 100.

The semiconductor substrate 100 may be formed of a silicon bulk wafer or an epitaxial wafer. The epitaxial wafer may include a crystalline material layer, that is, an epitaxial layer grown on a bulk substrate through an epitaxial process. The semiconductor substrate 100 is not limited to bulk wafers or epitaxial wafers and may be formed using various wafers such as polished wafers, annealed wafers, and Silicon On Insulator (SOI) wafers.

In some example embodiments, the semiconductor substrate 100 may include a P-type semiconductor substrate. For example, the semiconductor substrate 100 may be formed of a P-type silicon substrate. In some example embodiments, the semiconductor substrate 100 may include a P-type bulk substrate and a P-type or N-type epitaxial layer grown thereon. In some example embodiments, the semiconductor substrate 100 may include an N-type bulk substrate and a P-type or N-type epitaxial layer grown thereon. Alternatively, the semiconductor substrate 100 may be formed of an organic plastic substrate.

A device isolation structure DTI is arranged in the semiconductor substrate 100, and a plurality of pixels PXs may be defined by the device isolation structure DTI. The device isolation structure DTI may be arranged between one of a plurality of photoelectric conversion regions 101 and the photoelectric conversion region 101 adjacent thereto. One photoelectric conversion region 101 and another photoelectric conversion region 101 adjacent thereto may be physically and electrically separated by the device isolation structure DTI. The device isolation structure DTI may be arranged in each of the plurality of photoelectric conversion regions 101 arranged in a matrix form. The device isolation structure DTI may refract incident light incident on the photoelectric conversion region 101. The device isolation structure DTI may prevent or reduce photocharges generated by incident light from moving to another adjacent photoelectric conversion region 101 by random drift.

A photoelectric conversion region 101 and a well region 107 may be arranged in each of the plurality of pixels PXs, respectively. The photoelectric conversion region 101 may be arranged to be spaced apart from the first surface 100a of the semiconductor substrate 100. The photoelectric conversion region 101 may be, for example, a region doped with N-type impurities. A first photoelectric conversion device PD1 and a second photoelectric conversion device PD2 may be formed in the photoelectric conversion region 101.

The well region 107 may be arranged adjacent to the first surface 100a of the semiconductor substrate 100. The well region 107 may be, for example, a region doped with P-type impurities, and may be formed by doping the semiconductor substrate 100 with P-type impurities. A device isolation layer STI defining an active region and a floating diffusion region FD may be formed on the first surface 100a of the semiconductor substrate 100.

A gate electrode constituting a transistor may be formed on the first surface 100a of the semiconductor substrate 100. For example, the transistor may include a first transmission transistor TX1 and a second transmission transistor TX2 configured to transmit, to the floating diffusion region FD, charges generated by the first photoelectric conversion device PD1 and the second photoelectric conversion device PD2. In addition, for example, the transistor may include a reset transistor (e.g., RX in FIG. 3) configured to periodically reset the charges stored in the floating diffusion region FD, an amplification transistor (e.g., SF in FIG. 3) configured to operate as a source follower and buffer a signal according to charges stored in the floating diffusion region (FD ACL), and a selection transistor (e.g., SX in FIG. 3) that serves as switching and addressing to select the pixel PX. However, the plurality of transistors are not limited thereto.

In FIG. 2, it has been illustrated that a first transmission gate TG1 constituting a first transmission transistor TX1 and a second transmission gate TG2 constituting a second transmission transistor TX2 are formed of a recess gate type (for example, a dual recess gate type including two recess gate structures) extending from the first surface 100a of the semiconductor substrate 100 into the semiconductor substrate 100, but the shapes of the first transmission gate TG1 and the second transmission gate TG2 are not limited thereto. A first transmission gate insulation layer TGI1 may be arranged between the semiconductor substrate 100 and the first transmission gate TG1, and a second transmission gate insulation layer TGI2 may be arranged between the semiconductor substrate 100 and the second transmission gate TG2. For example, as the first transmission gate TG1 and the second transmission gate TG2 are formed in a recess gate type, parts of the first transmission gate insulation layer TGI1 and the second transmission gate insulation layer TGI2 may extend inside the semiconductor substrate 100.

The device isolation structure DTI may be formed inside the trench penetrating the semiconductor substrate 100 from the first surface 100a to the second surface 100b of the semiconductor substrate 100. That is, the device isolation structure DTI may extend vertically from the first surface 100a to the second surface 100b of the semiconductor substrate 100, and the vertical thickness of the device isolation structure DTI may be substantially the same or the same as the vertical thickness of the semiconductor substrate 100. The device isolation structure DTI may be defined as a deep trench isolation (DTI) layer formed in the semiconductor substrate 100. The device isolation structure DTI may be a front-side deep trench isolation (FDTI) layer formed by etching from the first surface 100a to the second surface 100b of the semiconductor substrate 100. However, the embodiments are not limited thereto, and the device isolation structure DTI may be a back-side deep trench isolation (BDTI) layer formed by etching from the second surface 100b of the semiconductor substrate 100 toward the first surface 100a thereof.

The width of the device isolation structure DTI may gradually decrease from the first surface 100a to the second surface 100b of the semiconductor substrate 100, although the device isolation structure DTI has a substantially uniform or uniform width in one direction. However, an image sensor according to some example embodiments is not limited thereto, and the width of the device isolation structure DTI may gradually increase from the first surface 100a of the semiconductor substrate 100 to the second surface 100b thereof, and the width of the device isolation structure DTI may decrease from the first surface 100a of the semiconductor substrate 100 toward the center of the semiconductor substrate 100 and then gradually increase from the center of the semiconductor substrate 100 to the second surface 100b of the semiconductor substrate 100.

The device isolation structure DTI may include an insulating layer 103 formed conformally on the sidewall of the trench and a conductive layer 102 filling the inside of the trench on the insulating layer 103. In some example embodiments, the insulating layer 103 may include a metal oxide such as hafnium oxide, aluminum oxide, tantalum oxide, and the like. In this case, the insulating layer 103 may act as a negative fixed charge layer, but the technical ideas of the inventive concepts are not limited thereto. In some example embodiments, the insulating layer 103 may include an insulating material such as silicon oxide, silicon nitride, silicon oxynitride, or the like, or may include air.

In some example embodiments, the conductive layer 102 may include at least one of undoped polysilicon, metal silicide, and a metal-containing layer. After a trench defining the shape of the device isolation structure DTI is formed, the conductive layer 102 may be formed along the surface of the trench and the conductive layer 102 may be formed to fill the inside of the trench.

The conductive layer 102 may not fill a part of the inside of the trench, and the bottom surface of the conductive layer 102 may be at a higher level than the first surface 100a of the semiconductor substrate 100. That is, the bottom surface of the conductive layer 102 may be spaced apart from the first surface 100a of the semiconductor substrate 100 by a predetermined (or, alternatively, desired or selected) distance in the vertical direction D3.

A conductive contact 119 may be electrically connected to an external wiring layer to apply a negative voltage to the device isolation structure DTI. The conductive contact 119 may be connected to the conductive layer 102 of the device isolation structure DTI. In some example embodiments, the plurality of pixels included in the pixel array (e.g., 110 of FIG. 1) may be placed in the central region of the semiconductor substrate 100, and the conductive contact 119 may be placed in the peripheral region of the semiconductor substrate 100 surrounding the central region of the semiconductor substrate 100.

When a negative voltage is applied to the device isolation structure DTI through the conductive contact 119, holes in the photoelectric conversion region 101 may move toward the interface of the device isolation structure DTI and accumulate. Accordingly, dark current of the image sensor may be reduced from occurring. In this drawing, the conductive contact 119 is illustrated as an example to be provided on the second surface 100b of the semiconductor substrate 100, but the conductive contact 119 may be provided on the first surface 100a of the semiconductor substrate 100.

The wiring structure 111 may be arranged on the first surface 100a of the semiconductor substrate 100. The wiring structure 111 may include wirings 113 and contact plugs. The contact plugs may extend in a vertical direction and electrically connects wirings 113 on different layers to each other. Interlayer insulating layers 111a, 111b, and 111c may be stacked and arranged on the first surface 100a of the semiconductor substrate 100.

The wiring structure 111 may be electrically connected to gate electrodes or active regions of transistors included in the pixel PX. Through the contact plugs and wirings 113, the floating diffusion region FD may be electrically connected to the transistors (e.g., reset transistor RX or amplification transistor SF of FIG. 3) that make up the pixel PX. In addition, through the contact plugs and the wirings 113, the floating diffusion region FD placed under the first photoelectric conversion device PD1 and the floating diffusion region FD placed under the second photoelectric conversion device PD2 may be electrically connected to each other. In addition, through the contact plugs and the wirings 113, floating diffusion regions FD included in different pixels PXs may be electrically connected to each other.

The wiring structure 111 may include at least one of polysilicon doped with or not doped with impurities, metal, metal silicide, metal nitride, or a metal-containing layer. For example, the wiring structure 111 may include tungsten, aluminum, copper, tungsten silicide, titanium silicide, tungsten nitride, titanium nitride, doped polysilicon, etc.

The interlayer insulating layers 111a, 111b, and 111c may cover the first transmission gate TG1 and the second transmission gate TG2. A plurality of contact plugs and a plurality of wirings 113 may be arranged in the interlayer insulating layers 111a, 111b, and 111c. The interlayer insulating layers 111a, 111b, and 111c may include an insulating material such as silicon oxide, silicon nitride, silicon oxynitride, or the like.

Color filters CF and microlenses ML may be arranged on the second surface 100b of the semiconductor substrate 100. An anti-reflection layer 132 and first and second insulation layers 134 and 136 may be arranged between the second surface 100b of the semiconductor substrate 100 and the color filters CF. The anti-reflection layer 132 may prevent or reduce light reflection so that light incident on the second surface 100b of the semiconductor substrate 100 may smoothly reach the first photoelectric conversion device PD1 and the second photoelectric conversion device PD2. The second insulating layer 136 may be provided to cover the conductive contact 119.

The color filters CF and the microlenses ML may be formed to correspond to each pixel PX. The color filters CF may include color filters of red, green, or blue depending on the pixel PX. The color filters CF may be two-dimensionally arranged, and may include a yellow filter, a magenta filter, and a cyan filter. In addition, the color filters CF may further include a white filter.

The microlens ML have a convex shape and may have a predetermined (or, alternatively, desired or selected) radius of curvature. The microlens ML may be formed of a light-transmitting resin, and may concentrate incident light into respective pixel regions.

FIG. 3 is a circuit diagram of a pixel PX included in the pixel array of FIG. 1. Two photoelectric conversion devices included in one pixel PX are illustrated in FIG. 3, but two or more photoelectric conversion devices may be included in one pixel PX.

Referring to FIG. 3, one pixel PX may include a first photoelectric conversion device PD1, a second photoelectric conversion device PD2, a first transmission transistor TX1, a second transmission transistor TX2, a reset transistor RX, an amplification transistor SF, and a selection transistor SX. However, in some example embodiments, at least one of the reset transistor RX, the amplification transistor SF, and the selection transistor SX may be omitted.

The first photoelectric conversion device PD1 and the second photoelectric conversion device PD2 may generate photocharges that vary according to the intensity of light. For example, the first photoelectric conversion device PD1 and the second photoelectric conversion device PD2 are P-N junction diodes that may generate charges (for example, electrons as negative charges, and holes as positive charges) in proportion to the amount of light incident to the P-N junction diodes. The first photoelectric conversion device PD1 and the second photoelectric conversion device PD2 are examples of photoelectric conversion devices, and may include at least one of photo transistors, photo gates, pinned photo diodes (PPD), and a combination thereof.

The first transmission transistor TX1 may transmit the photocharges generated by the first photoelectric conversion device PD1 to a floating diffusion region FD according to a first transmission control signal TS1, and the second transmission transistor TX2 may transmit the photocharges generated by the second photoelectric conversion device PD2 to the floating diffusion region FD according to a second transmission control signal TS2. When each of the first transmission transistor TX1 and the second transmission transistor TX2 is turned on, photocharges generated in each of the first photoelectric conversion device PD1 and the second photoelectric conversion device PD2 may be transmitted to one floating diffusion region FD and accumulated and stored in the floating diffusion region FD.

The reset transistor RX may periodically reset charges accumulated in the floating diffusion region FD. The drain electrode of the reset transistor RX is connected to the floating diffusion region FD, and the source electrode thereof is connected to the power supply voltage VPIX. When the reset transistor RX is turned on according to the reset control signal RS, the power supply voltage VPIX connected to the source electrode of the reset transistor RX is transmitted to the floating diffusion region FD. When the reset transistor RX is turned on, charges accumulated in the floating diffusion region FD may be discharged to reset the floating diffusion region FD.

The amplification transistor SF may be controlled according to the amount of photocharges accumulated in the floating diffusion region FD. The amplification transistor SF may be a buffer amplifier and may buffer a signal according to a charge charged in the floating diffusion region FD. The amplification transistor SF may amplify the potential change in the floating diffusion region FD and output the amplified potential change as a pixel signal VOUT through a column output line (e.g., one of CLO_0 to CLO_n−1 in FIG. 1).

The selection transistor SX may have a drain terminal connected to a source terminal of the amplification transistor SF, and may output a pixel signal VOUT to the CDS 151 through a column output line in response to a selection signal SEL.

FIG. 3 illustrates some example embodiments in which photocharges generated in each of the first photoelectric conversion device PD1 and the second photoelectric conversion device PD2 accumulate in the same floating diffusion region FD, but the embodiments are not limited thereto. The photocharges generated by the first photoelectric conversion device PD1 may accumulate in a first floating diffusion region, and the photocharges generated by the second photoelectric conversion device PD2 may accumulate in a second floating diffusion region separated from the first floating diffusion region.

FIG. 4A is a diagram of a pixel included in an image sensor according to some example embodiments, and shows an example of a pixel included in the pixel array of FIG. 1. FIG. 4B is a diagram of a pixel of an image sensor according to some example embodiments, and is a cross-sectional view taken along line A1-A2 of FIG. 4A.

FIG. 4A may be a layout viewed from a first surface 100a to a second surface 100b of a semiconductor substrate (e.g., 100 of FIG. 2). The structure of the pixel described with reference to FIG. 4A may be repeatedly placed on the pixel array 110 in an illustrated arrangement structure or in a structure in which the illustrated arrangement structure is symmetrically converted. In the description of FIG. 4B, redundant descriptions of the same reference numerals as in FIG. 2 will be omitted.

Referring to FIGS. 4A and 4B, the device isolation structure DTI may be formed to surround one pixel and may be separated from the other pixels. That is, one pixel may be defined by the device isolation structure DTI.

The device isolation structure DTI may be formed to separate the first photoelectric conversion device PD1 and the second photoelectric conversion device PD2 from each other in the pixel. For example, the device isolation structure DTI may be formed to extend in one direction (e.g., the second direction D2) of FIG. 2) horizontal to the main surface of the semiconductor substrate within the pixel.

An open region OW1 that partially exposes between the first photoelectric conversion device PD1 and the second photoelectric conversion device PD2 may be formed in the device isolation structure DTI. The open region OW1 may refer to a region in which the device isolation structure DTI is not formed, and the width of the open region OW1 may be variously configured.

The open region OW1 may be arranged at the edge of the pixel. In some example embodiments, a ground contact GND for applying a ground voltage to the pixel may be formed in the open region OW1. For example, the ground contact GND that provides a ground voltage applied to each of the first photoelectric conversion device PD1 and the second photoelectric conversion device PD2 may be formed in the open region OW1.

Compared to a comparative example in which the open region OW1 is placed at the center of the pixel, the image sensor according to some example embodiments includes the open region OW1 placed at the edge of the pixel, thereby limiting the movement of photocharges generated in each of the first and second photoelectric conversion devices PD1 and PD2 and improving AF contrast characteristics.

The pixel PX may include a doped passivation layer PL. In some example embodiments, the passivation layer PL may be formed to surround the device isolation structure DTI. For example, the passivation layer PL may be formed to surround each of the first photoelectric conversion device PD1 and the second photoelectric conversion device PD2. In some example embodiments, the passivation layer PL may include silicon doped with impurities of a specific conductive type, for example, a P type.

The passivation layer PL may also be formed in the open region OW1. In the open region OW1, the passivation layer PL may extend from the second surface 100b of the semiconductor substrate 100 to a specific depth in the vertical direction perpendicular to the semiconductor substrate 100. The depth of the passivation layer PL in the open region OW1 may be less than the depth of the passivation layer PL in a region other than the open region OW1.

The passivation layer PL has a conductivity type opposite to that of the photoelectric conversion region 101 in which the first photoelectric conversion device PD1 and the second photoelectric conversion device PD2 are formed, thereby providing a potential barrier, that is, a charge overflow barrier, between the first photoelectric conversion device PD1 and the second photoelectric conversion device PD2. That is, a potential well between the first photoelectric conversion device PD1 and the second photoelectric conversion device PD2 may be formed by the passivation layer PL, and the linearity of a full well of each of the first photoelectric conversion device PD1 and the second photoelectric conversion device PD2 may be improved.

Compared to the comparative example in which the open region OW1 is placed at the center of the pixel in forming the passivation layer PL in the open region OW1, as the open region OW1 is placed at the edge of the pixel, the image sensor according to this embodiment may be easier to form the passivation layer PL uniformly in the open region OW1 within the pixel array. Therefore, even if the width of the open region OW1 is increased, the passivation layer PL may be formed uniformly, the width of the open region OW1 may be easily adjusted, and the process of forming the passivation layer PL may be easily controlled.

In some example embodiments, a ground contact GND that applies a ground voltage to the pixel PX may be arranged under the passivation layer PL (e.g., in the reverse direction of D3 in FIG. 2) in the open region OW1. Alternatively, in some example embodiments, the floating diffusion region FD and at least one of transistors included in the pixel may be arranged under the passivation layer PL in the open region OW1.

The floating diffusion region FD, a first transmission gate TG1, and a first transistor TR1 including a first gate GL1 and a first active region AR1 may be arranged under the first photoelectric conversion device PD1. The floating diffusion region FD, a second transmission gate TG2, and a second transistor TR2 including a second gate GL2 and a second active region AR2 may be arranged under the second photoelectric conversion device PD2. The first transistor TR1 and the second transistor TR2 may be a transistor constituting a pixel, for example, the reset transistor RX, the amplification transistor SF, or the selection transistor SX of FIG. 3. The floating diffusion region FD placed under the first photoelectric conversion device PD1 and the floating diffusion region FD placed under the second photoelectric conversion device PD2 may be electrically/physically connected to each other through a wiring structure (e.g., 111 in FIG. 2).

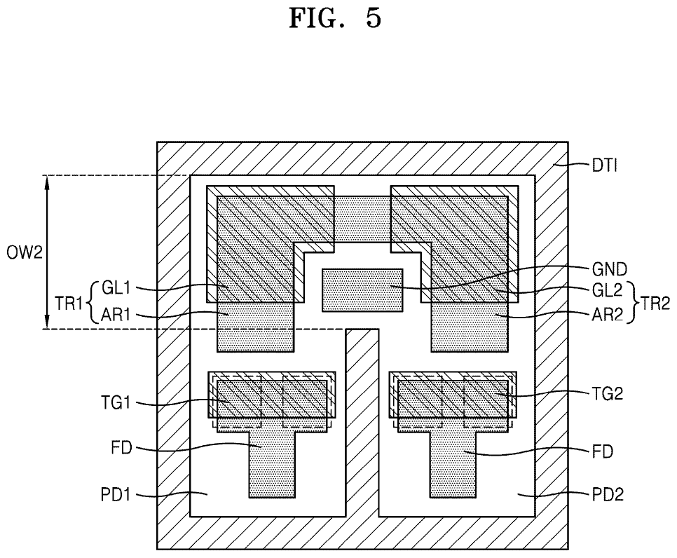

FIGS. 5 to 11 are diagrams of a pixel included in an image sensor according to some example embodiments, and show examples of the pixel included in the pixel array of FIG. 1, respectively. FIGS. 5 to 11 may be layouts viewed from a first surface 100a to a second surface 100b of a semiconductor substrate (e.g., 100 of FIG. 2). The structure of the pixel described with reference to FIGS. 5 to 11 may be repeatedly placed on the pixel array 110 in an illustrated arrangement structure or in a structure in which the illustrated arrangement structure is symmetrically converted.

Referring to FIG. 5, an open region OW2 that partially exposes between the first photoelectric conversion device PD1 and the second photoelectric conversion device PD2 may be formed in the device isolation structure DTI. The open region OW2 may be arranged at the edge of the pixel. In some example embodiments, a ground contact GND for applying a ground voltage to a pixel may be arranged in the open region OW2, and the first active region AR1 of the first transistor TR1 and the second active region AR2 of the second transistor TR2 may be arranged in the open region OW2. The first active region AR1 and the second active region AR2 may be connected to each other.

The first transistor TR1 and the second transistor TR2 may be a transistor constituting a pixel, for example, the reset transistor RX, the amplification transistor SF, or the selection transistor SX of FIG. 3. For example, the first transistor TR1 may be an amplification transistor SF and the second transistor TR2 may be a selection transistor SX. Alternatively, when the pixel includes a first reset transistor and a second reset transistor connected in series between the terminal to which the power voltage (VPIX in FIG. 3) is applied and the floating diffusion region FD, instead of the reset transistor RX, the first transistor TR1 may be a first reset transistor and the second transistor TR2 may be a second reset transistor. The floating diffusion region FD placed under the first photoelectric conversion device PD1 and the floating diffusion region FD placed under the second photoelectric conversion device PD2 may be electrically connected to each other through a wiring structure (e.g., 111 in FIG. 2).

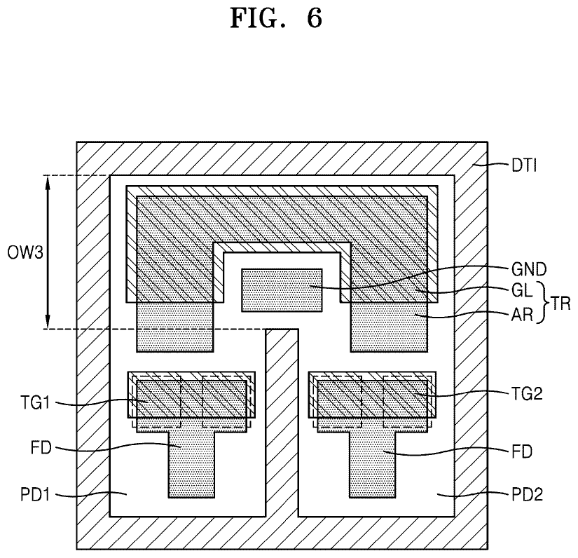

Referring to FIG. 6, an open region OW3 that partially exposes between the first photoelectric conversion device PD1 and the second photoelectric conversion device PD2 and is arranged in the edge of the pixel may be formed in the device isolation structure DTI. In some example embodiments, a ground contact GND for applying a ground voltage to a pixel may be arranged in the open region OW3, and a transistor TR including a gate GL and an active region AR may be arranged in the open region OW3. The transistor TR may be a transistor constituting a pixel, for example, the reset transistor RX, the amplification transistor SF, or the selection transistor SX of FIG. 3. In some example embodiments, the transistor TR may be the amplification transistor SF, and the noise characteristics of the pixel may be improved by forming the amplification transistor SF relatively large, for example, covering more surface area than other example embodiments) through the open region OW3.

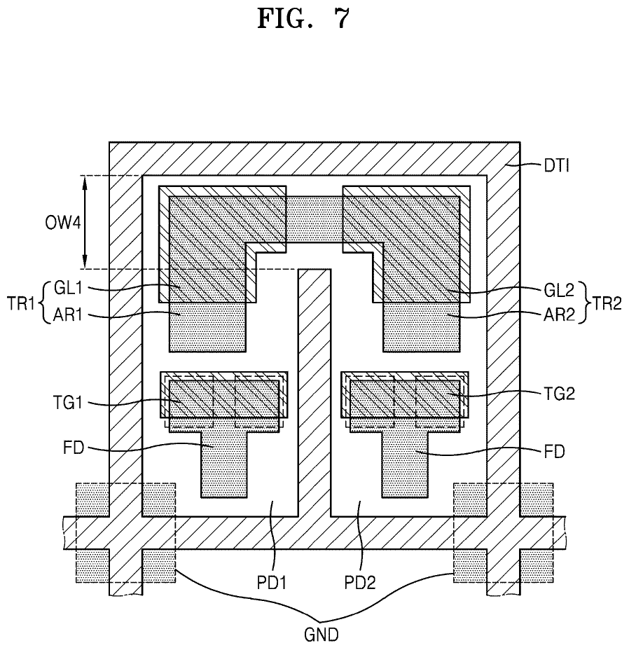

Referring to FIG. 7, an open region OW4 that partially exposes between the first photoelectric conversion device PD1 and the second photoelectric conversion device PD2 and is arranged in the edge of the pixel may be formed in the device isolation structure DTI. In some example embodiments, the first active region AR1 of the first transistor TR1 and the second active region AR2 of the second transistor TR2 may be arranged in the open region OW4. The first active region AR1 and the second active region AR2 may be connected to each other.

The ground contact GND for applying a ground voltage to the pixel may be formed under each of the first photoelectric conversion device PD1 and the second photoelectric conversion device PD2, and may be formed under each of the edges of the first photoelectric conversion device PD1 and the second photoelectric conversion device PD2.

In some example embodiments, the ground contact GND may be formed to be in contact with the device isolation structure DTI. For example, as a device isolation structure DTI that separates four pixels is formed after one ground contact pattern is formed across the four pixels, the ground contact pattern may be separated to form four separate ground contacts GND to apply the ground voltage to each of the four pixels.

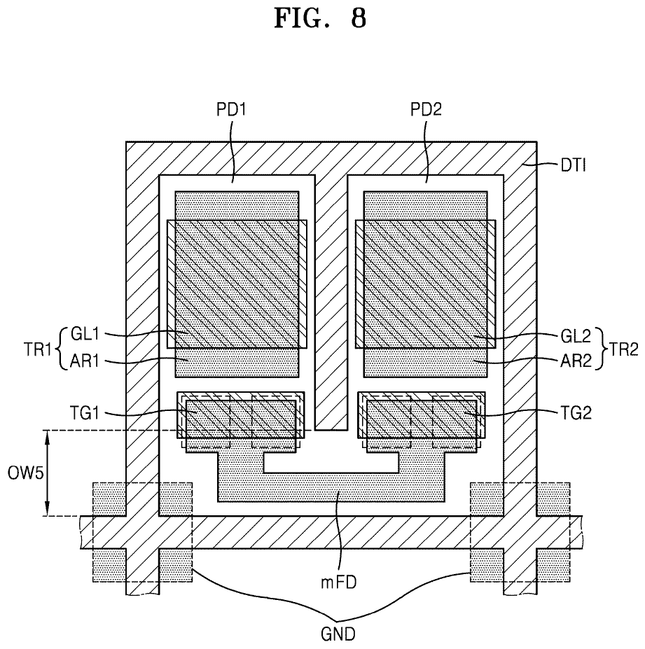

Referring to FIG. 8, an open region OW5 that partially exposes between the first photoelectric conversion device PD1 and the second photoelectric conversion device PD2 and is arranged in the edge of the pixel may be formed in the device isolation structure DTI. In some example embodiments, the floating diffusion region mFD may be arranged in the open region OW5. The floating diffusion region mFD includes a first region under the first photoelectric conversion device PD1, a second region under the second photoelectric conversion device PD2, and a third region in the open region OW5, and the first region and the second region may be physically/electrically connected to each other through the third region.

As described with reference to FIG. 4, compared with the example in which the floating diffusion region FD arranged under the first photoelectric conversion device PD1 and the floating diffusion region FD arranged under the second photoelectric conversion device PD2 are electrically/physically connected to each other through a wiring structure (e.g., 111 of FIG. 2), the capacitance of the floating diffusion region mFD may relatively decrease and the signal-to-noise ratio (SNR) of the pixel signal generated from the pixel may increase. Therefore, when a relatively great capacitance is required, the floating diffusion region FD of FIG. 4 may be formed, or when a pixel signal with an increased SNR is required, the floating diffusion region FD of FIG. 8 may be formed, but the embodiments are not limited thereto.

The ground contact GND for applying a ground voltage to the pixel may be formed under each of the first photoelectric conversion device PD1 and the second photoelectric conversion device PD2, and may be formed under each of the edges of the first photoelectric conversion device PD1 and the second photoelectric conversion device PD2. In some example embodiments, the ground contact GND may be formed to be in contact with the device isolation structure DTI. For example, as a device isolation structure DTI that separates four pixels is formed after one ground contact pattern is formed across the four pixels, the ground contact pattern may be separated to form four separate ground contacts GND to apply the ground voltage to each of the four pixels.

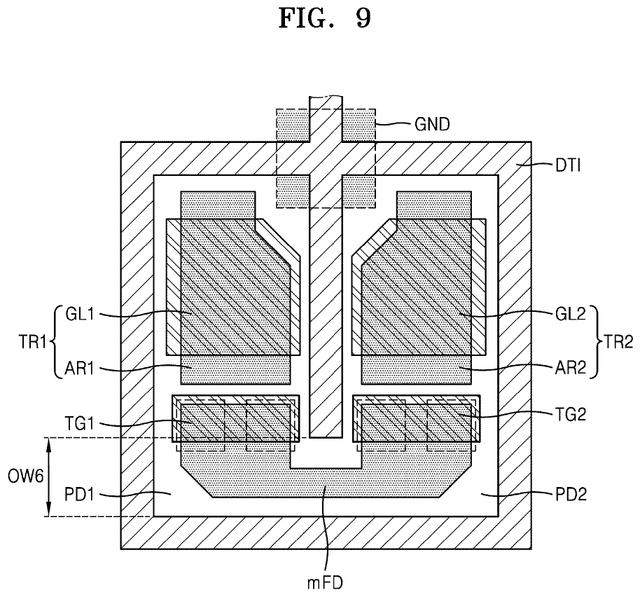

Referring to FIG. 9, an open region OW6 that partially exposes between the first photoelectric conversion device PD1 and the second photoelectric conversion device PD2 and is arranged in the edge of the pixel may be formed in the device isolation structure DTI. In some example embodiments, the floating diffusion region mFD may be arranged in the open region OW6. The floating diffusion region mFD includes a first region under the first photoelectric conversion device PD1, a second region under the second photoelectric conversion device PD2, and a third region in the open region OW5, and the first region and the second region may be physically/electrically connected to each other through the third region.

The ground contact GND for applying a ground voltage to the pixel may be formed under each of the first photoelectric conversion device PD1 and the second photoelectric conversion device PD2, and may be formed under each of the edges of the first photoelectric conversion device PD1 and the second photoelectric conversion device PD2. In some example embodiments, the ground contact GND may be formed to be in contact with the device isolation structure DTI. For example, since one ground contact pattern is formed over two pixels, as two pixels are separated, and a device isolation structure DTI separating the first photoelectric conversion device PD1 and the second photoelectric conversion device PD2 included in each of the two pixels is formed, four ground contacts GND separated to apply a ground voltage to the first photoelectric conversion devices PD1 and the second photoelectric conversion devices PD2 included in each of the two pixels may be formed by separating the ground contact pattern.

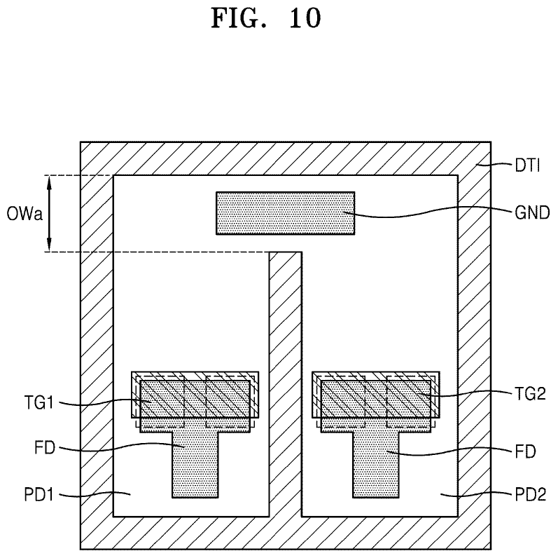

Referring to FIG. 10, an open region OWa that partially exposes between the first photoelectric conversion device PD1 and the second photoelectric conversion device PD2 and is arranged in the edge of the pixel may be formed in the device isolation structure DTI. In some example embodiments, a ground contact GND may be arranged in the open region OWa.

The floating diffusion region FD and the first transmission gate TG1 may be arranged under the first photoelectric conversion device PD1, and the floating diffusion region FD and the second transmission gate TG2 may be arranged under the second photoelectric conversion device PD2. The floating diffusion region FD placed under the first photoelectric conversion device PD1 and the floating diffusion region FD placed under the second photoelectric conversion device PD2 may be electrically/physically connected to each other through a wiring structure (e.g., 111 in FIG. 2).

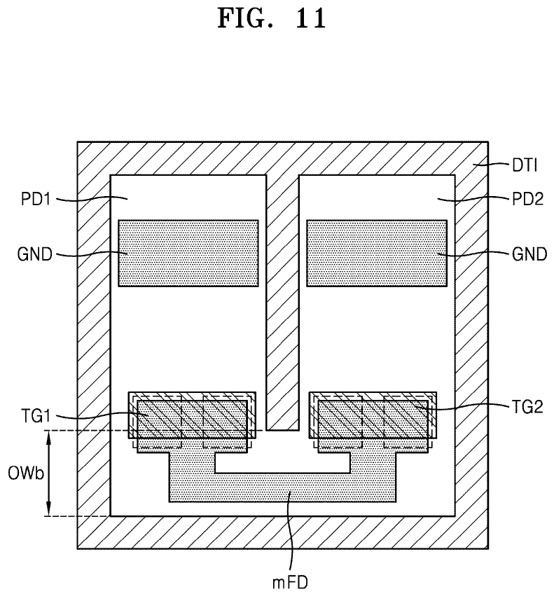

Referring to FIG. 11, an open region OWb that partially exposes between the first photoelectric conversion device PD1 and the second photoelectric conversion device PD2 and is arranged in the edge of the pixel may be formed in the device isolation structure DTI. In some example embodiments, the floating diffusion region mFD may be arranged in the open region OWb. The floating diffusion region mFD includes a first region under the first photoelectric conversion device PD1, a second region under the second photoelectric conversion device PD2, and a third region in the open region OWb, and the first region and the second region may be physically/electrically connected to each other through the third region.

Ground contacts GND may be arranged under the first photoelectric conversion device PD1 and the second photoelectric conversion device PD2, respectively. The ground contact GND may be spaced apart from the device isolation structure DTI.

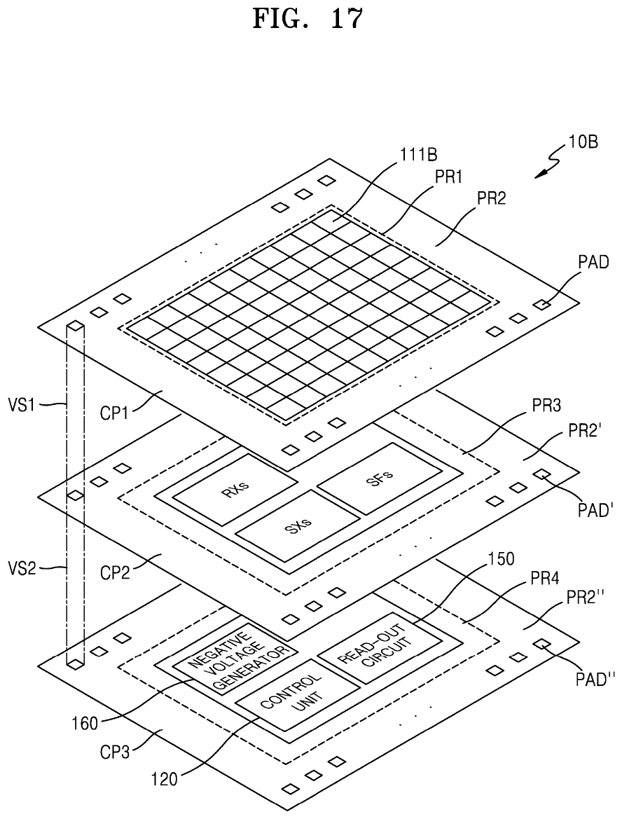

Referring to FIGS. 10 and 11, some of the components included in the pixel may be arranged on a first chip (e.g., CP1 in FIG. 17), and some of the components included in the pixel may be arranged on a second chip (e.g., CP2 in FIG. 17). The layouts shown in FIGS. 10 and 11 may be layouts viewed from the first surface 100a to the second surface 100b of the semiconductor substrate (e.g., 100 of FIG. 2) of the first chip CP1.

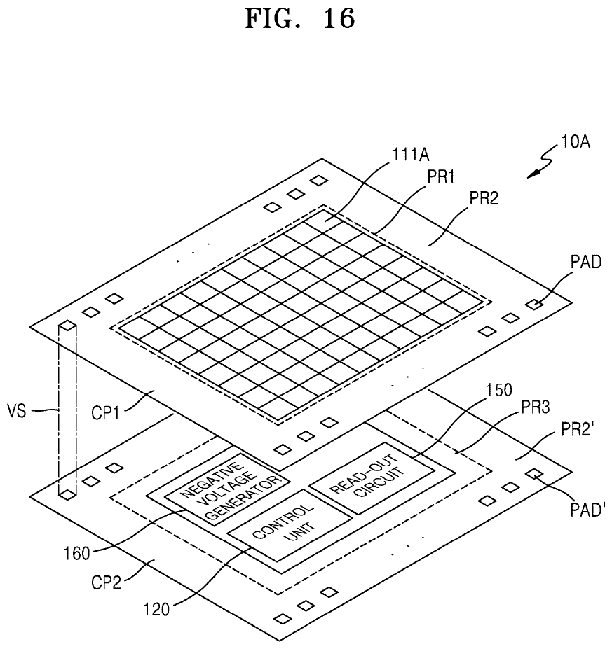

For example, in the first chip CP1, the first photoelectric conversion device PD1, the second photoelectric conversion device PD2, the first transmission transistor TX1, the second transmission transistor TX2, the floating diffusion region FD or mFD, and the ground contact GND are arranged, and in the second CP2, the reset transistor RX, the amplification transistor SF, and the selection transistor SX are arranged. Meanwhile, in some example embodiments, the components PD1, PD2, TX1, TX2, FD, mFD, GND, RX, SF, and SX of the pixels described with reference to FIGS. 4A and 5 to 9 may be arranged on the same chip (e.g., CP1 of FIG. 16).

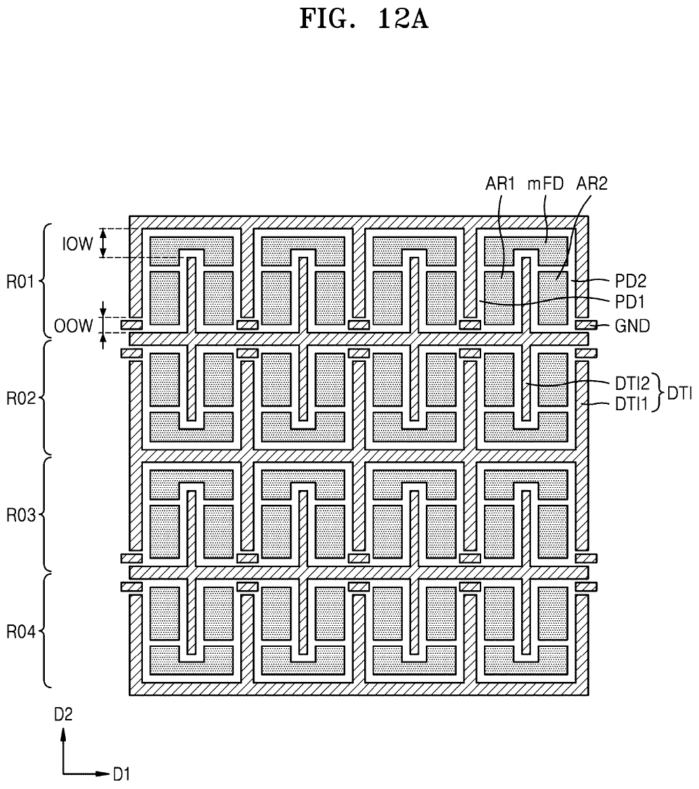

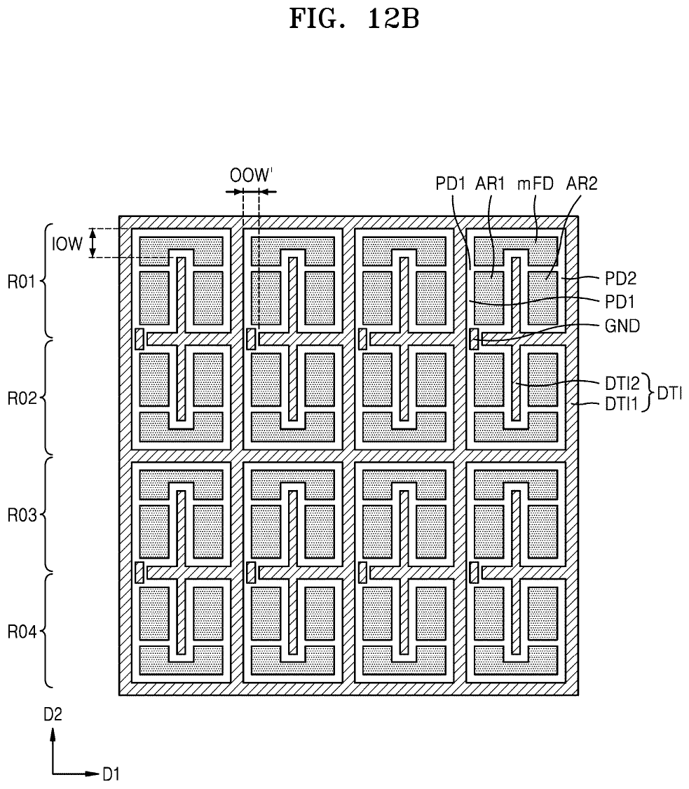

FIGS. 12A and 12B are diagrams of a pixel array included in an image sensor according to some example embodiments, and illustrate examples of the pixel array of FIG. 1, respectively. FIGS. 12A to 12B may be layouts viewed from a first surface 100a to a second surface 100b of a semiconductor substrate (e.g., 100 of FIG. 2).

Referring to FIG. 12A, pixels may be arranged on each of a plurality of rows. For example, pixels may be placed in a first row R01 to a fourth row R04. Pixels placed in the first row R01 and the pixels placed in the second row R02 may have a symmetrical arrangement structure based on the axis of a first direction D1, that is, the row direction, and pixels placed in the third row R03 and the pixels placed in the fourth row R04 may have a symmetrical arrangement structure based on the axis of the first direction D1. In some example embodiments, the pixel may include a first photoelectric conversion device PD1, a second photoelectric conversion device PD2, a first active region AR1 constituting a first transistor, a second active region AR2 constituting a second transistor, a floating diffusion region mFD, and a ground contact GND.

The device isolation structure DTI may include a first device isolation structure DTI1 and a second device isolation structure DTI2. The pixels may be separated from each other by the first device isolation structure DTI1, and the first photoelectric conversion device PD1 and the second photoelectric conversion device PD2 included in the pixel may be separated from each other by the second device isolation structure DTI2. The device isolation structure DTI including the first device isolation structure DTI1 and the second device isolation structure DTI2 may entirely connected without separation in the pixel array 110. That is, the first device isolation structure DTI1 and the second device isolation structure DTI2 may be in contact with each other, and the device isolation structures DTI may be continuously formed. Therefore, it may be possible (for example, easily) to apply a negative voltage to the conductive layer (e.g., 102 in FIG. 4) of each of the first device isolation structure DTI1 and the second device isolation structure DTI2 through a conductive contact (e.g., 119 in FIG. 4).

The first device isolation structure DTI1 may include an external open region OOW, and the second device isolation structure DTI2 may include an internal open region IOW. Each of the open regions OW1 to OW6, OWa and OWb described with reference to FIGS. 4A and 5 to 11 may correspond to the internal open region IOW. Therefore, the floating diffusion region mFD, the active region of the transistor constituting the pixel (e.g., AR1 and AR2), or the gate of the transistor may be arranged in the internal open region IOW.

A ground contact GND may be arranged in the external open region OOW. In some example embodiments, the external open region OOW may be formed to open between two pixels arranged at the same row, that is, between two pixels arranged adjacent to each other in the first direction D1. Accordingly, the two pixels arranged adjacent to each other in the first direction D1 may share the ground contact GND with each other.

In some example embodiments, the width of the external open region OOW may be less than the width of the internal open region IOW. However, the embodiments are not limited thereto, and the width of the internal open region IOW and the width of the external open region OOW may be freely modified.

Referring to FIG. 12B, the first device isolation structure DTI1 may include an external open region OOW′, and the second device isolation structure DTI2 may include an internal open region IOW. A ground contact GND may be arranged in the external open region OOW′. In some example embodiments, the external open region OOW′ may be formed to open between two pixels arranged at different rows, for example, between two pixels arranged adjacent to each other in the second direction D2. Accordingly, the two pixels arranged adjacent to each other in the second direction D2 may share the ground contact GND with each other.

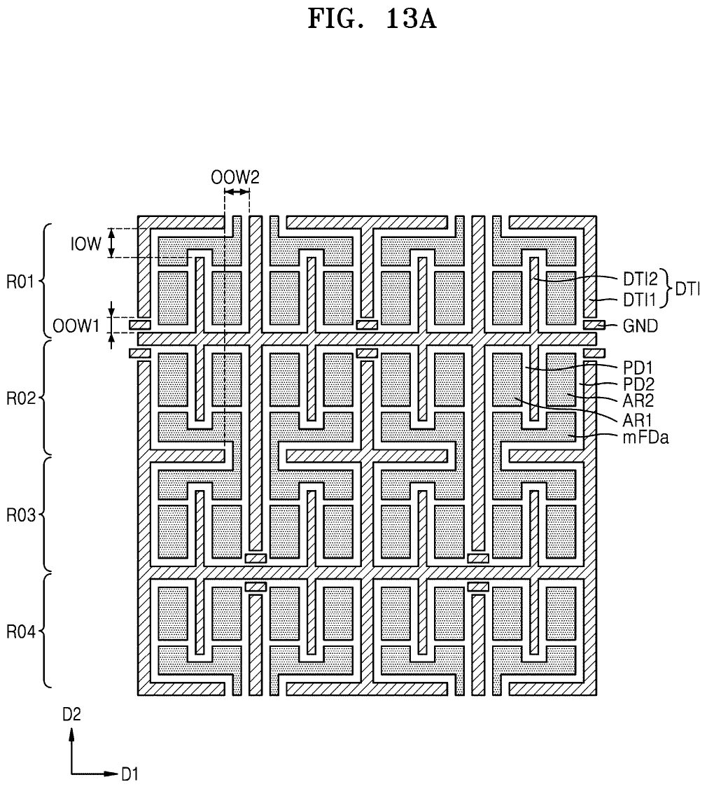

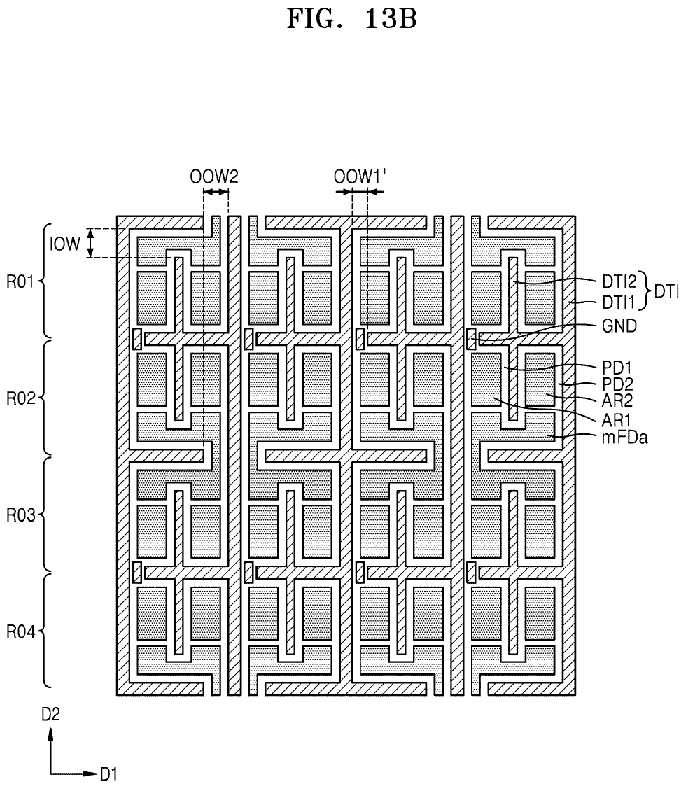

FIGS. 13A and 13B are diagrams of a pixel array included in an image sensor according to some example embodiments, and illustrate examples of the pixel array of FIG. 1, respectively. FIGS. 13A to 13B may be layouts viewed from a first surface 100a to a second surface 100b of a semiconductor substrate (e.g., 100 of FIG. 2).

Referring to FIG. 13A, pixels may be arranged on each of a plurality of rows. For example, pixels may be placed in a first row R01 to a fourth row R04. Pixels placed in the first row R01 and the pixels placed in the second row R02 may have a symmetrical arrangement structure based on the axis of a first direction D1, and pixels placed in the third row R03 and the pixels placed in the fourth row R04 may have a symmetrical arrangement structure based on the axis of the first direction D1. In some example embodiments, the pixel may include a first photoelectric conversion device PD1, a second photoelectric conversion device PD2, a first active region AR1 constituting a first transistor, a second active region AR2 constituting a second transistor, a floating diffusion region mFDa, and a ground contact GND.

The first device isolation structure DTI1 may include a first external open region OOW1 and a second external open region OOW2, and the second device isolation structure DTI2 may include an internal open region IOW. Each of the open regions OW1 to OW6, OWa and OWb described with reference to FIGS. 4A and 5 to 11 may correspond to the internal open region IOW. Therefore, the floating diffusion region mFDa, the active regions of the transistor constituting the pixel (e.g., AR1 and AR2), or the gate of the transistor may be arranged in the internal open region IOW.

A ground contact GND may be arranged in the first external open region OOW1. In some example embodiments, the first external open region OOW1 may be formed to open between two pixels placed on the same row, that is, between two pixels placed adjacent to each other in the first direction D1, and two pixels placed adjacent to each other in the first direction D1 may share a ground contact GND.

A floating diffusion region mFDa may be arranged in the second external open region OOW2. In some example embodiments, the second external open region OOW2 may be formed to open between two pixels arranged at different rows, that is, between two pixels arranged adjacent to each other in the second direction D2. Accordingly, the two pixels arranged adjacent to each other in the second direction D2 may share the floating diffusion region mFDa. For example, among pixels arranged in the second row R02 and the third row R03, two pixels arranged adjacent to each other in the second direction D2 may share the floating diffusion region mFDa. As the two pixels share the floating diffusion region mFDa, the total capacitance of the floating diffusion region mFDa may be increased.

Referring to FIG. 13B, the first device isolation structure DTI1 may include a first external open region OOW1′ and a second external open region OOW2, and the second device isolation structure DTI2 may include an internal open region IOW. A ground contact GND may be arranged in the first external open region OOW1′. In some example embodiments, the first external open region OOW1′ may be formed to open between two pixels arranged at different rows, for example, between two pixels arranged adjacent to each other in the second direction D2. For example, among pixels arranged in the first row R01 and the second row R02, two pixels arranged adjacent to each other in the second direction D2 may share a ground contact GND.

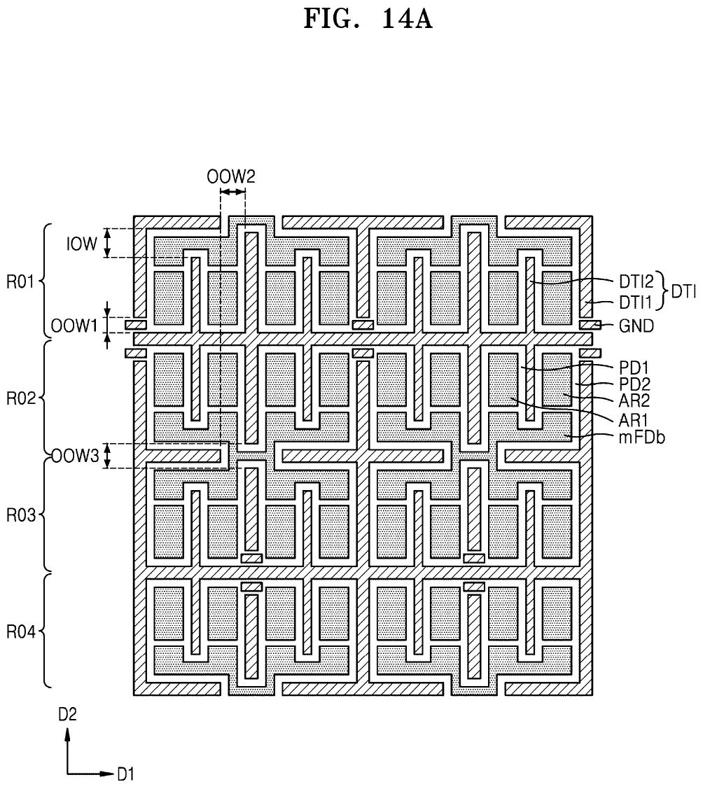

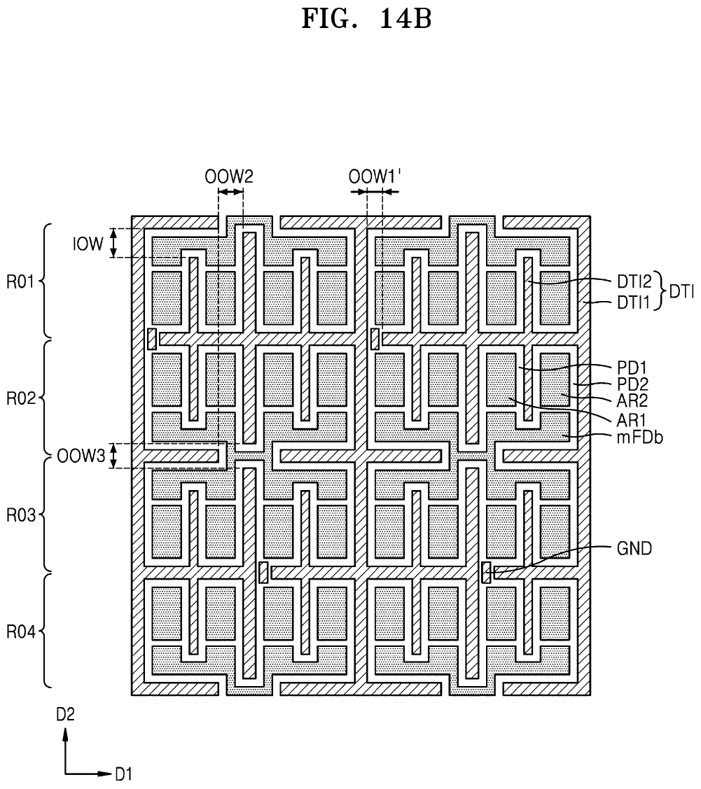

FIGS. 14A and 14B are diagrams of a pixel array included in an image sensor according to some example embodiments, and illustrate examples of the pixel array of FIG. 1, respectively. FIGS. 14A to 14B may be layouts viewed from a first surface 100a to a second surface 100b of a semiconductor substrate (e.g., 100 of FIG. 2).

Referring to FIG. 14A, pixels may be arranged on each of a plurality of rows. For example, pixels may be placed in a first row R01 to a fourth row R04. Pixels placed in the first row R01 and the pixels placed in the second row R02 may have a symmetrical arrangement structure based on the axis of a first direction D1, and pixels placed in the third row R03 and the pixels placed in the fourth row R04 may have a symmetrical arrangement structure based on the axis of the first direction D1. In some example embodiments, the pixel may include a first photoelectric conversion device PD1, a second photoelectric conversion device PD2, a first active region AR1 constituting a first transistor, a second active region AR2 constituting a second transistor, a floating diffusion region mFDb, and a ground contact GND.

The first device isolation structure DTI1 may include a first external open region OOW1, a second external open region OOW2, and a third external open region OOW3, and the second device isolation structure DTI2 may include an internal open region IOW. Each of the open regions OW1 to OW6, OWa and OWb described with reference to FIGS. 4A and 5 to 11 may correspond to the internal open region IOW. Therefore, the floating diffusion region mFDb, the active regions of the transistor constituting the pixel (e.g., AR1 and AR2), or the gate of the transistor may be arranged in the internal open region IOW.

A ground contact GND may be arranged in the first external open region OOW1. In some example embodiments, the first external open region OOW1 may be formed to open between two pixels placed on the same row, that is, between two pixels placed adjacent to each other in the first direction D1, and two pixels placed adjacent to each other in the first direction D1 may share a ground contact GND.

A floating diffusion region mFDb may be arranged in the second external open region OOW2 and the third external open region OOW3. In some example embodiments, the second external open region OOW2 may be formed to open between two pixels arranged at different rows, that is, between two pixels arranged adjacent to each other in the second direction D2. In addition, in some example embodiments, the third external open region OOW3 may be formed to open between two pixels placed on the same row, that is, between two pixels placed adjacent to each other in the first direction D1. Accordingly, four pixels arranged adjacent to each other in the first direction D1 and the second direction D2 may share the floating diffusion region mFDb. For example, among pixels placed in the second row R02 and the third row R03, four pixels placed adjacent to each other in the first direction D1 and the second direction D2 may share the floating diffusion region mFDb. As the four pixels share the floating diffusion region mFDb, the total capacitance of the floating diffusion region mFDb may be increased.

Referring to FIG. 14B, the first device isolation structure DTI1 may include a first external open region OOW1′, a second external open region OOW2, and a third external open region OOW3, and the second device isolation structure DTI2 may include an internal open region IOW. A ground contact GND may be arranged in the first external open region OOW1′. In some example embodiments, the first external open region OOW1′ may be formed to open between two pixels arranged at different rows, for example, between two pixels arranged adjacent to each other in the second direction D2. For example, among pixels arranged in the first row R01 and the second row R02, two pixels arranged adjacent to each other in the second direction D2 may share a ground contact GND.

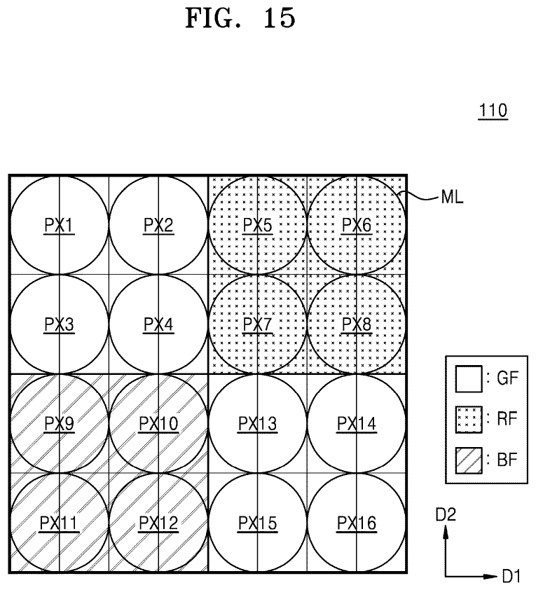

FIG. 15 is a diagram for explaining a pixel array 110 of an image sensor according to some example embodiments, and illustrates an example of the pixel array 110 of FIG. 1.

Referring to FIG. 15, the pixel array 110 may include a plurality of pixel groups, for example, first to sixteenth pixels PX1 to PX16. Each of the first to sixteenth pixels PX1 to PX16 may include a first photoelectric conversion device and a second photoelectric conversion device arranged adjacent to each other in the first direction D1, and may include one microlens ML arranged on the first photoelectric conversion device and the second photoelectric conversion device.

The pixel array 110 may include color filters to sense various colors. Each of the first to sixteenth pixels PX1 to PX16 may include one of a green color filter GF, a red color filter RF, and a blue color filter BF. In some example embodiments, the arrangement ratio of the red color filter RF, the green color filter GF, and the blue color filter BF in the pixel array 110 may be 1:2:1.

In some example embodiments, four pixel groups arranged adjacent to each other from among the plurality of pixels (e.g., first to sixteenth pixels PX1 to PX16) included in the pixel array 110 may include the same color filter. The color filters may be arranged to form a Bayer pattern in units of four of the first to sixteenth pixels PX1 to PX16. For example, each of the first to fourth pixels PX1 to PX4 and the thirteenth to sixteenth pixels PX13 to PX16 may include the green color filter GF, each of the fifth to eighth pixels PX5 to PX8 may include the red color filter RF, and each of the ninth to twelfth pixels PX9 to PX12 may include the blue color filter BF. However, the embodiments are not limited thereto, and a color filter may form a Bayer pattern in units of one pixel, a color filter may form a Bayer pattern in units of nine pixels, or a color filter may form a Bayer pattern in units of sixteen pixels.

FIGS. 16 and 17 are diagrams illustrating image sensors 10A and 10B according to some example embodiments.

Referring to FIG. 16, an image sensor 10A may be a stacked image sensor including a first chip CP1 and a second chip CP2, which are stacked in a vertical direction. The image sensor 10A may be one in which the image sensor 10 described with reference to FIG. 1 or the like is implemented.

The first chip CP1 may include a pixel region PR1 and a pad region PR2, and the second chip CP2 may include a circuit region PR3 and a pad region PR2′. The pixels described with reference to FIGS. 2 to 15 may be formed in the pixel region PR1. In some example embodiments, the first photoelectric conversion device PD1, the second photoelectric conversion device PD2, the first transmission transistor TX1, the second transmission transistor TX2, the floating diffusion region FD, the reset transistor RX, the amplification transistor SF, and the selection transistor SX of FIG. 3 may be formed in the pixel region PR1 of the first chip CH1.

A plurality of transistors may be formed in the circuit region PR3 of the second chip CP2. For example, the control unit 120, the signal processing unit 130, the row driver 140, the readout circuit 150, and the negative voltage generator 160 may be formed in the circuit region PR3 of the second chip CP2.

The pad region PR2 of the first chip CP1 may include a plurality of first conductive pads PAD, and the pad region PR2′ of the second chip CP2 may include a plurality of second conductive pads PAD′. The plurality of first conductive pads PAD may correspond to the plurality of second conductive pads PAD′ and may be electrically connected to the plurality of second conductive pads PAD′ by a via structure VS. The negative voltage generated by the negative voltage generator 160 may be applied to the device isolation structure formed on the first chip CP1 through a corresponding second conductive pad PAD′ among the plurality of second conductive pads PAD′, the via structure VS, and a corresponding first conductive pad PAD among the plurality of first conductive pads PAD.

Referring to FIG. 17, an image sensor 10B may be a stacked image sensor including a first chip CP1, a second chip CP2, and a third chip CP3, which are stacked vertically. The image sensor 10B may be one in which the image sensor 10 described with reference to FIG. 1 or the like is implemented.

At least some of the pixels described with reference to FIGS. 2 to 15 may be formed in the pixel region PR1 of the first chip CP1. In some example embodiments, the first photoelectric conversion device PD1, the second photoelectric conversion device PD2, the first transmission transistor TX1, the second transmission transistor TX2, and the floating diffusion region FD of the pixel PX described with reference to FIG. 3 may be formed in the pixel region PR1 of the first chip CP1, and a ground contact for providing a ground voltage to the pixel may also be formed in the pixel region PR1 of the first chip CP1. Meanwhile, a plurality of reset transistors RXs, a plurality of amplification transistors SFs, and a plurality of selection transistors SXs included in a plurality of pixels may be formed in the circuit region PR3 of the second chip CP2.

A plurality of transistors may be formed in the circuit region PR4 of the third chip CP3. For example, the control unit 120, the signal processing unit 130, the row driver 140, the readout circuit 150, and the negative voltage generator 160 may be formed in the circuit region PR4 of the third chip CP3.

The pad region PR2 of the first chip CP1 may include a plurality of first conductive pads PAD, the pad region PR2′ of the second chip CP2 may include a plurality of second conductive pads PAD′, and the pad region PR2″ of the third chip CP3 may include a plurality of third conductive pads PAD″. The plurality of first conductive pads PAD, the plurality of second conductive pads PAD′, and the plurality of third conductive pads PAD″ may be electrically connected to each other by a first via structure VS1 and a second via structure VS2. The negative voltage generated by the negative voltage generator 160 may be applied to a device isolation structure formed on the first chip CP1 through a corresponding first conductive pad PAD″ among the plurality of third conductive pads PAD″, the second via structure VS2, a corresponding first conductive pad PAD′ among the plurality of second conductive pads PAD′, the first via structure VS1, and a corresponding first conductive pad PAD among the plurality of first conductive pads PAD.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

While the inventive concepts have been particularly shown and described with reference to some example embodiments thereof, it will be understood that various changes in form and details may be made therein without departing from the spirit and scope of the following claims.

1. An image sensor comprising:
a semiconductor substrate including a pixel array including a plurality of pixels;
a first photoelectric conversion device and a second photoelectric conversion device inside the semiconductor substrate and included in each of the plurality of pixels;
microlenses on the first photoelectric conversion device and the second photoelectric conversion device; and
a device isolation structure between the plurality of pixels and between the first photoelectric conversion device and the second photoelectric conversion device,
the device isolation structure opening a part between the first photoelectric conversion device and the second photoelectric conversion device, including an open region at each edge of the plurality of pixels, and being continuous in the pixel array.

2. The image sensor of claim 1, wherein a ground contact configured to provide a ground voltage to the first photoelectric conversion device and the second photoelectric conversion device is in the open region.

3. The image sensor of claim 1, wherein a floating diffusion region configured to accumulate photocharges generated by each of the first photoelectric conversion device and the second photoelectric conversion device is in the open region.

4. The image sensor of claim 1, wherein an active region or gate of a transistor included in each of the plurality of pixels is in the open region.

5. The image sensor of claim 4, wherein the transistor comprises at least one of a reset transistor configured to reset a floating diffusion region configured to accumulate photocharges generated in the first photoelectric conversion device and the second photoelectric conversion device, an amplification transistor configured to amplify a signal according to the photocharges accumulated in the floating diffusion region, and a selection transistor configured to be connected to the amplification transistor and output a pixel signal.

6. The image sensor of claim 1, further comprising
a ground contact configured to provide a ground voltage applied to the first photoelectric conversion device and the second photoelectric conversion device,
wherein the ground contact is under the edge of each of the first photoelectric conversion device and the second photoelectric conversion device.

7. (canceled)

8. The image sensor of claim 1, further comprising a passivation layer in the open region and doped with p-type impurities.

9. An image sensor comprising:
a first photoelectric conversion device and a second photoelectric conversion device inside a semiconductor substrate and included in each of a plurality of pixels;
microlenses on the first photoelectric conversion device and the second photoelectric conversion device;
a first device isolation structure between the plurality of pixels; and
a second device isolation structure between the first photoelectric conversion device and the second photoelectric conversion device,
the second device isolation structure opening a part between the first photoelectric conversion device and the second photoelectric conversion device, including an internal open region at each edge of the plurality of pixels, and the first device isolation structure and the second device isolation structure contacting each other.

10. The image sensor of claim 9, wherein the first device isolation structure comprises an external open region configured to open a portion between adjacent pixels.

11. The image sensor of claim 10, wherein a ground contact configured to provide a ground voltage to the adjacent pixels is in the external open region.

12. The image sensor of claim 10, wherein a floating diffusion region configured to accumulate photocharges generated in each of first photoelectric conversion devices and second photoelectric conversion devices included in two adjacent pixels is in the external open region.

13. The image sensor of claim 10, wherein a floating diffusion region configured to accumulate photocharges generated in each of first photoelectric conversion devices and second photoelectric conversion devices included in four adjacent pixels is in the external open region.

14. The image sensor of claim 9, wherein a ground contact configured to provide a ground voltage to the first photoelectric conversion device and the second photoelectric conversion device is in the internal open region.

15. The image sensor of claim 9, wherein a floating diffusion region configured to accumulate photocharges generated by each of the first photoelectric conversion device and the second photoelectric conversion device is in the internal open region.

16. The image sensor of claim 9, wherein an active region or gate of a transistor included in each of the plurality of pixels is in the internal open region.

17.-19. (canceled)

20. An image sensor comprising:
a first chip including a semiconductor substrate including a device isolation structure isolating a plurality of pixels; and
a second chip under the first chip and comprising a negative voltage generator configured to apply a negative voltage to the device isolation structure,
the first chip including a first photoelectric conversion device and a second photoelectric conversion device inside the semiconductor substrate and included in each of the plurality of pixels; and
microlenses on the first photoelectric conversion device and the second photoelectric conversion device, the device isolation structure being between the first photoelectric conversion device and the second photoelectric conversion device, and
the device isolation structure opening a part between the first photoelectric conversion device and the second photoelectric conversion device, including an internal open region at each edge of the plurality of pixels, and continuous in the first chip.

21. The image sensor of claim 20, wherein the first chip further comprises:
a floating diffusion region;
a first transmission transistor and a second transmission transistor configured to transmit, to the floating diffusion region, charges generated by the first photoelectric conversion device and the second photoelectric conversion device;
a reset transistor configured to reset the floating diffusion region;
an amplification transistor configured to amplify a signal according to photocharges accumulated in the floating diffusion region; and
a selection transistor, connected to the amplification transistor, configured to output a pixel signal.

22. The image sensor of claim 20, further comprising a third chip between the first chip and the second chip,
wherein
the first chip further comprises
a floating diffusion region; and
a first transmission transistor and a second transmission transistor configured to transmit, to the floating diffusion region, charges generated by the first photoelectric conversion device and the second photoelectric conversion device, and
the third chip comprises
a reset transistor configured to reset the floating diffusion region;
an amplification transistor configured to amplify a signal according to photocharges accumulated in the floating diffusion region; and
a selection transistor, connected to the amplification transistor, configured to output a pixel signal.

23. The image sensor of claim 20, wherein a ground contact configured to provide a ground voltage to the first photoelectric conversion device and the second photoelectric conversion device is in the internal open region.

24. The image sensor of claim 20, wherein a floating diffusion region configured to accumulate photocharges generated by each of the first photoelectric conversion device and the second photoelectric conversion device is in the internal open region.

25.-29. (canceled)
